(19) United States
(12) Patent Application Publication
(10) Pub. No.: US 2016/0186057 A1
(43) Pub. Date: Jun. 30, 2016

(54) ETCHING LIQUID COMPOSITION FOR MULTILAYER CONTAINING COPPER AND MOLYBDENUM AND PROCESS FOR ETCHING THEREOF

(71) Applicant: MITSUBISHI GAS CHEMICAL COMPANY, INC., Chiyoda-ku (JP)

(72) Inventors: Kunio YUBE, Tokyo (JP); Satoshi Tamai, Tokyo (JP)

(73) Assignee: MITSUBISHI GAS CHEMICAL COMPANY, INC., Chiyoda-ku (JP)

(21) Appl. No.: 15/066,138

(22) Filed: Mar. 10, 2016

Related U.S. Application Data
(62) Division of application No. 13/858,413, filed on Apr. 8, 2013, now abandoned.

(30) Foreign Application Priority Data
Apr. 10, 2012 (JP) 2012-089469

(51) Int. Cl. C09K 13/00; G03F 7/32; G03F 7/20

(52) U.S. Cl. CPC C09K 13/00; G03F 7/20; G03F 7/32

(57) ABSTRACT

There is provided an etching liquid composition for a multilayer film containing copper and molybdenum. The etching liquid composition comprises: (A) a peroxosulfate ion source; (B) a copper ion source; and (C) at least one nitrogen compound source selected from the group consisting of ammonia, ammonium ions, amines, and alkyl ammonium ions and has pH 3.5 to 9.

### RELATED APPLICATION

This patent application is based upon and claims the benefit of priority from the prior Japanese Patent Application No. 89469/2012, filed on Apr. 10, 2012, the entire contents of which are incorporated herein by reference.

### BACKGROUND OF THE INVENTION

1. Field of Invention

The present invention relates to a liquid invention. More particularly, the present invention relates to an etching liquid composition for a multilayer film containing copper and molybdenum and an etching method using the same.

2. Background Art

Aluminum or aluminum alloys have hitherto been generally used as wiring materials for display devices such as flat panel displays. In such aluminum-based wiring materials, an increase in size and resolution of displays leads to a problem of a signal delay attributable to characteristics such as resistance of wiring, making it difficult to provide a uniform screen display.

Copper has an advantage over aluminum in terms of lower resistance, but on the other hand, is disadvantageous in that, when copper is used in a gate wiring, the adhesion between a substrate such as glass and copper is unsatisfactory. Further, the use of copper in a source-drain wiring sometimes poses a problem of copper oxidation due to diffusion of copper into an underlying silicon semiconductor film and diffusion of oxygen from an oxide semiconductor film. In order to solve the above problems, studies have been made on a wiring having a multilayer structure in which a copper layer is provided through a barrier film formed of a metal that has a high adhesion to substrates such as glass and has a barrier capability that can allow diffusion into a silicon semiconductor film to be less likely to occur. Metals such as molybdenum and titanium are known as metals that simultaneously realize adhesion and barrier capability requirements, and a multilayer film having a two-layer structure composed of a copper layer and a layer of the metal or an alloy of the metal that are stacked on each other, and a multilayer film having a three-layer structure composed of the two layers constituting the two-layer structure and a layer of metal such as molybdenum or titanium provided on the copper layer for copper layer oxidation preventive purposes have been adopted.

The copper-containing multilayer structure wiring is obtained by forming coatings on a substrate such as glass by sputtering or a film forming process and performing etching using a resist or the like as a mask to form an electrode pattern. Etching methods include a wet method using an etching liquid and a dry method using an etching gas such as plasma. Advantageous properties required of the etching liquid used in the wet method include:

high processing accuracy;

no etching residue;

components that are stable, safe and easy to handle;

stable etching properties;

good wiring shape after etching; and

even speed and amount of etching of a large-area substrate regardless of sites in the substrate.

In general, etching liquids containing copper ions and halide ions are known as etching liquids for a copper etching process. Such liquids involve problems such as corrosion of apparatuses by halide ions and difficulties of regulating a wiring shape due to an excessively high etching speed.

Etching liquids for copper known in the art include acidic etching liquids containing hydrogen peroxide and an acid (for example, Japanese Patent Laid-Open No. 591/1986) and acidic etching liquids containing a peroxosulfate and an acid (for example, Japanese Patent Laid-Open No. 31838/1972). Further, ammoniacal alkaline etching liquids containing copper(II) ions and ammonia are also known (see, for example, Japanese Patent Laid-Open No. 243286/1985, PRINTED CIRCUIT ASSEMBLY MANUFACTURING, Fred W. Kear, MARCEL DEKKER,INC., Page140, 1987, and Zashchita Metallov (1987), Vol. 23(2), Page 295-7). The copper-containing multilayer film can be etched even with the ammoniacal alkaline etching liquid. Since, however, the ammoniacal alkaline etching liquid has high pH, a large amount of ammonia is volatilized, and, in some cases, a variation in etching speed occurs due to lowered ammonia concentration or a significant deterioration in working environment. Further, the high pH poses a problem of dissolution of the resist. In this case, the volatilization of ammonia from the etching liquid can be suppressed by bringing pH to a neutral region. This etching liquid, however, has a problem of the precipitation of residue in rinsing with water after etching. Further, the etching liquid has an additional problem that, when the etching liquid contains copper(II) ions and ammonia, in etching, for example, in particular, a large-area substrate with a spray-type etching apparatus, the speed of etching of the substrate varies depending upon the state of spraying (flow rate distribution), and, consequently, the etching results vary from sites to sites in the substrate.

Further, ammoniacal alkaline etching liquids containing ammonium peroxodisulfate, copper(II) ions, and ammonia are also known (for example, Japanese Patent Laid-Open No. 7137/1974). Since such alkaline liquids exhibit a high etching speed, difficulties are encountered in regulating the wiring shape. Further, such alkaline liquids have additional problems such as low stability of ammonium peroxodisulfate and the generation of gas and heat as a result of a decomposition reaction of peroxodisulate ions.

### SUMMARY OF THE INVENTION

The present inventors have now found that, in a liquid composition containing a peroxosulfate ion source, a copper ion source, and a specific nitrogen compound source such as ammonia, the above problems can be solved by bringing pH to a specific range.

Accordingly, an object of the present invention is to provide an etching liquid composition for a multilayer film containing copper and molybdenum, and an etching method for a multilayer film containing copper and molybdenum using the same.

According to the present invention, there is provided an etching liquid composition for a multilayer film containing copper and molybdenum, the liquid composition comprising:

(A) a peroxosulfate ion source;

(B) a copper ion source; and

(C) at least one nitrogen compound source selected from the group consisting of ammonia, ammonium ions, amines, and alkyl ammonium ions,

the liquid composition having pH 3.5 to 9.

In an embodiment of the liquid composition according to the present invention, the peroxosulfate ion source (A) is at least one compound selected from the group consisting of ammonium peroxodisulfate, potassium peroxodisulfate, sodium peroxodisulfate, and potassium hydrogen peroxomonosulfate.

In an embodiment of the liquid composition according to the present invention, the mixing ratio of the peroxosulfate ion source (A) to the copper ion source (B) is 0.01 to 20 on a molar basis.

In an embodiment of the liquid composition according to the present invention, the copper ion source (B) is at least one compound selected from the group consisting of copper, copper sulfate, copper nitrate, and copper acetate.

In an embodiment of the present invention, the nitrogen compound source (C) is at least one compound selected from the group consisting of ammonia, ammonium sulfate, ammonium nitrate, ammonium acetate, ammonium peroxodisulfate, and tetramethylammonium hydroxide.

In an embodiment of the liquid composition according to the present invention, the mixing ratio of the nitrogen compound source (C) to the copper ion source (B) is 4 to 100 on a molar basis.

In an embodiment of the liquid composition according to the present invention, the liquid composition further comprises (D) a carboxylate ion source.

In an embodiment of the liquid composition according to the present invention, the carboxylate ion source (D) is at least one compound selected from the group consisting of acetic acid, propionic acid, malonic acid, succinic acid, lactic acid and salts of the carboxylic acids, and acetic anhydride.

In an embodiment of the liquid composition according to the present invention, the mixing ratio of the carboxylate ion source (D) to the copper ion source (B) is 0.1 to 50 on a molar basis.

In an embodiment of the liquid composition according to the present invention, the liquid composition further comprises (E) a molybdate ion source.

According to another aspect of the present invention, there is provided an etching method for a multilayer film comprising copper and molybdenum, the etching method comprising

bringing the above liquid composition into contact with the multilayer film.

In an embodiment of the etching method according to the present invention, the multilayer film has a two-layer structure composed of a layer of molybdenum or a compound composed mainly of molybdenum and a layer of copper or a compound composed mainly of copper that are stacked on each other.

In an embodiment of the etching method according to the present invention, the multilayer film has a three-layer structure consisting of a layer of molybdenum or a compound composed mainly of molybdenum, a layer of copper or a compound composed mainly of copper, and a layer of molybdenum or a compound composed mainly of molybdenum that are stacked in that order.

According to still another aspect of the present invention, there is provided a process for producing a multilayer film wiring comprising a multilayer film provided on a substrate, the multilayer film comprising at least a molybdenum-containing layer and a copper-containing layer, the process comprising:

providing a layer of molybdenum and a layer of copper in that order on a substrate to form a multilayer film;

covering a resist on the multilayer film to form a resist film;

subjecting the resist film to exposure and development to form a predetermined resist pattern, thereby forming an etching object; and

bringing the above liquid composition into contact with the etching object to etch the multilayer film, thereby forming a multilayer wiring.

According to the liquid composition of the present invention, a wiring having a structure of a multilayer film containing copper and molybdenum can be etched at one time, and a good etching speed (about 0.1 to 1 μm/min) can be realized. Further, in a etching process, since a variation in etching speed upon a variation in flow of the liquid composition is so small that, in etching a large-area substrate by a spray method, even when the state of spraying of the liquid composition (flow rate distribution) varies depending upon sites in the substrate, uneven etching does not occur and, thus, the productivity and the quality of the substrate can be improved. Therefore, an etching liquid composition that can meet requirements for an increase in size of displays and an increase in resolution can be realized.

Further, in the liquid composition according to the present invention, even when copper and molybdenum are dissolved in etching, a variation in etching speed is so small that etching can be carried out for a long period of time. In etching, the dissolved copper and molybdenum are mixed into the liquid composition. These mixed components serve as the copper ion source (B) and the molybdate ion source (E), and, thus, the addition of the components free from the component (B) and the component (E) (that is, component (A), component (C), component (D), or component (F)) to the liquid composition during the etching can provide a formulation of the liquid composition before the etching. Consequently, the etching liquid composition can be used for a longer period of time.

Further, since the liquid composition has pH 3.5 to 9, the vaporization of ammonia is small and the liquid composition is easy to handle. Further, the production of gas and heat by a decomposition reaction of peroxosulfate ions is not significant, and, thus, etching can be carried out in a safe and stable manner.

### BRIEF DESCRIPTION OF THE DRAWINGS

FIG. 1 is a typical view of a cross section of a wiring having a structure of a multilayer film containing copper and molybdenum obtained by etching with an etching liquid composition according to the present invention.

FIG. 2 is a SEM (scanning electron microscopic) photograph of a cross section of a wiring having a structure of a multilayer film containing copper and molybdenum after etching in Example 1.

FIG. 3 is a SEM (scanning electron microscopic) photograph of a cross section of a wiring having a structure of a multilayer film containing copper and molybdenum after etching in Example 9.

FIG. 4 is a SEM (scanning electron microscopic) photograph of a cross section of a wiring having a structure of a multilayer film containing copper and molybdenum after etching in Comparative Example 1.

FIG. 5 is a SEM (scanning electron microscopic) photograph of a cross section of a wiring having a structure of a multilayer film containing copper and molybdenum after etching in Example 13.

FIG. 6 is a SEM (scanning electron microscopic) photograph of a cross section of a wiring having a structure of a multilayer film containing copper and molybdenum after etching in Example 17.

FIG. 7 is a SEM (scanning electron microscopic) photograph of a cross section of a wiring having a structure of a multilayer film containing copper and molybdenum after etching in Example 22.

FIG. 8 is a SEM (scanning electron microscopic) photograph of a cross section of a wiring having a structure of a multilayer film containing copper and molybdenum after etching in Example 25.

FIG. 9 is a SEM (scanning electron microscopic) photograph of a cross section of a wiring having a structure of a multilayer film containing copper and molybdenum after etching in Example 33.

### DETAILED DESCRIPTION OF THE INVENTION

### <Liquid Composition>

The etching liquid composition according to the present invention is used for a multilayer film containing copper and molybdenum, contains at least (A) a peroxosulfate ion source, (B) a copper ion source, and (C) a nitrogen compound source, and has pH 3.5 to 9. The etching liquid composition containing such specific components, when brought to pH 3.5 to 9, can realize etching of a wiring having a structure of a multilayer film containing copper and molybdenum at one time. A good etching speed (about 0.1 to 1 μm/min) can be realized. Further, in a etching process, a variation in etching speed upon a variation in flow of the liquid composition is so small that, in etching a large-area substrate by a spray method, even when the state of spraying of the liquid composition (flow rate distribution) varies depending upon sites in the substrate, uneven etching does not occur and, thus, the productivity and the quality of the substrate can be improved. Therefore, an etching liquid composition that can meet requirements for an increase in size of displays and an increase in resolution can be realized. Further, since the liquid composition has pH 3.5 to 9, the vaporization of ammonia is small and the liquid composition is easy to handle. Further, the production of gas and heat by a decomposition reaction of peroxosulfate ions is not significant, and, thus, etching can be carried out in a safe and stable manner.

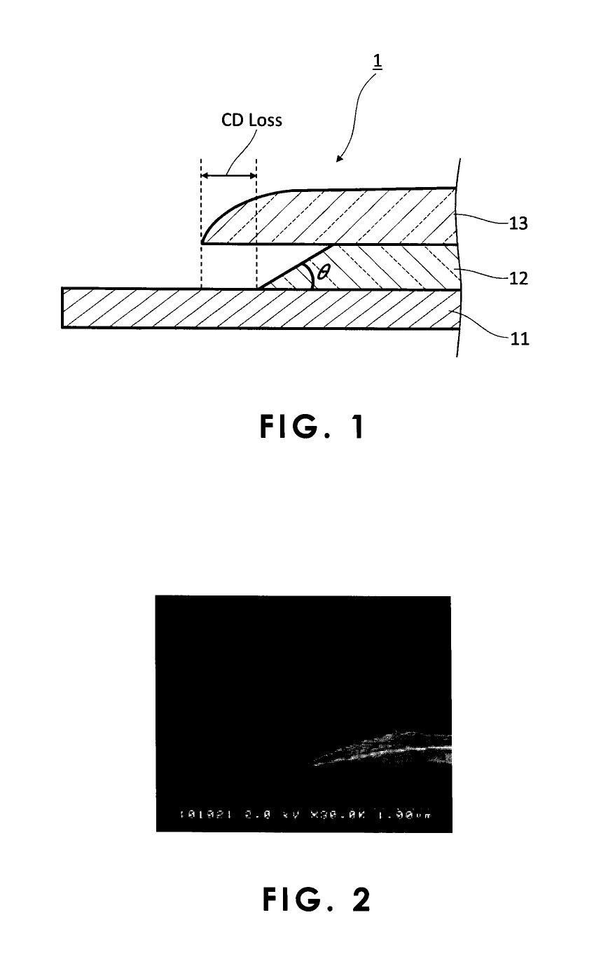

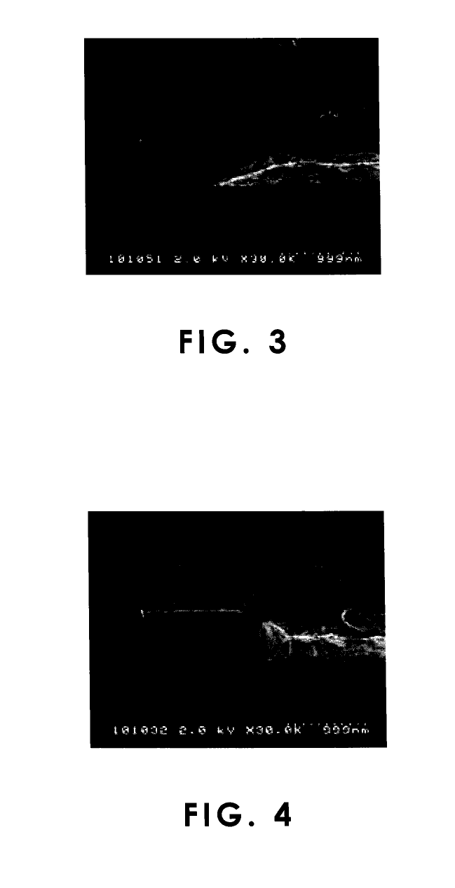

The etching liquid composition according to the present invention is for a multilayer film containing copper and molybdenum, and a wiring of a multilayer film having a good shape can be provided. The good wiring shape will be described. FIG. 1 is a typical view of a cross section of a wiring having a structure of a multilayer film containing copper and molybdenum. A wiring 1 having a structure of a multilayer film can be obtained by forming a multilayer film 12 including a copper layer and a molybdenum layer on a substrate 11 such as glass, covering the multilayer film 12 with a resist 13, subjecting the resist 13 to exposure and development to form a desired resist pattern, and bringing the treated multilayer film as an etching object into contact with the liquid composition to etch the multilayer film.

For the multilayer film wiring 1 thus obtained by etching, it is important that an angle (θ) of an etching surface of an end of the wiring having a multilayer structure that makes with the substrate be a forward tapered angle. The angle is preferably 15 to 75 degrees, more preferably 20 to 70 degrees, particularly preferably 25 to 70 degrees. A taper angle of smaller than 15 degrees is disadvantageous in that the wiring has a decreased sectional area and, in a fine wiring, is likely to be broken. When the taper angle is larger than 75 degrees, the coverage in the formation of a film such as an insulating film as a layer overlying the wiring is disadvantageously small. The horizontal distance from the end of a barrier film constituting a lower layer (bottom) in the wiring having a multilayer structure to the end of the resist 13 (a bottom critical dimension loss (abbreviated to CD loss) is preferably not more than 2.5 μm, more preferably not more than 1.8 μm, particularly preferably not more than 1.5 μm. When the bottom CD loss is larger than 2.5 μm, the sectional area of the wiring is disadvantageously small. Further, the etching loss is increased. In the present invention, a multilayer film wiring having a good shape can be obtained by etching a multilayer film containing copper and molybdenum with a liquid composition that contains a peroxosulfate ion source, a copper ion source, and a specific nitrogen compound source such as ammonia and has a specific pH range. The components constituting the liquid composition according to the present invention will be described.

### (A) Peroxosulfate Ion Source

The peroxosulfate ion source (sometimes hereinafter referred to simply as component (A)) contained in the present invention functions as an oxidizing agent and acts directly or indirectly for etching of the multilayer film containing copper and molybdenum. Any peroxosulfate ion source that can supply peroxosulfate ions can be used without particular limitation. Examples of preferred peroxosulfate ion sources include peroxodisulfates such as ammonium peroxodisulfate, potassium peroxodisulfate, and sodium peroxodisulfate; peroxomonosulfates such as potassium hydrogen peroxomonosulfate; and peroxomonosulfuric acid (also known as Caro's acid). These peroxosulfate ion sources may be used solely or as a mixture of a plurality of them. Among them, ammonium peroxodisulfate, potassium peroxodisulfate, sodium peroxodisulfate, and potassium hydrogen peroxomonosulfate are preferred from the viewpoints of excellent dissolution in water and stability in the liquid composition, and improving the etching capability. Particularly preferred are ammonium peroxodisulfate, potassium peroxodisulfate, and sodium peroxodisulfate.

Ammonium salts such as ammonium peroxodisulfate described above function as the component (A) and also as a nitrogen compound source (C) that will be described later. For example, when ammonium peroxodisulfate is contained in the liquid composition according to the present invention, the content of the component (A) is the total content of other peroxosulfate ion sources and the ammonium salt of peroxodisulfuric acid.

The peroxosulfate ion source (component (A)) is preferably contained in an amount of 0.001 to 2 moles, more preferably 0.002 to 1.5 moles, particularly preferably 0.004 to 1 mole, per kg of the liquid composition. The mixing ratio of the peroxosulfate ion source (component (A)) to the copper ion source (component (B)) which will be described later is preferably 0.01 to 20, more preferably 0.02 to 18, particularly preferably 0.03 to 15, on a molar basis. When the content of the peroxosulfate ion source (component (A)) in the liquid composition according to the present invention is in the above-defined range, the etching speed and the sectional shape of the wiring are further improved. Further, an even etching speed can be obtained regardless of uneven spray coating.

### (B) Copper Ion Source

Any copper ion source that can supply copper(II) ions can be used as the copper ion source (sometimes hereinafter referred to simply as component (B)) contained in the liquid composition without particular limitation. Examples of preferred copper ion sources include copper and copper salts such as copper sulfate, copper nitrate, copper acetate, cupric chloride, cupric bromide, cupric fluoride, cupric iodide, and ammonium copper sulfate. These copper ion sources may be used solely or in a combination of two or more of them. Among them, copper, copper sulfate, copper nitrate, and copper acetate are more preferred, and copper sulfate and copper nitrate are particularly preferred.

Ammonium copper double salts such as ammonium copper sulfate described above function as the component (B) and also as a nitrogen compound source (C) which will be described later. For example, when ammonium copper sulfate is contained in the liquid composition according to the present invention, the content of the component (B) is the total content of other copper ion sources and the ammonium copper double salt. Copper salts of carboxylic acids such as copper acetate described above function as the component (B) and also as a carboxylate ion source (component (D)). For example, when copper acetate is contained in the liquid composition according to the present invention, the content of the component (B) is the total content of other copper ion sources and copper acetate.

The copper ion source (component (B)) is preferably contained in an amount of 0.001 to 2 moles, more preferably 0.005 to 1.5 moles, particularly preferably 0.01 to 1 mole, per kg of the liquid composition. When the content of the copper ion source (component (B)) in the liquid composition according to the present invention is in the above-defined range, the etching speed and the sectional shape of the wiring can be further improved.

### (C) Nitrogen Compound Source

The nitrogen compound source (sometimes hereinafter referred to simply as component (C)) contained in the liquid composition according to the present invention is selected from the group consisting of ammonia, ammonium ions, amines, and alkylammonium ions. Any nitrogen compound source that can supply nitrogen compounds can be used without particular limitation, and examples of preferred nitrogen compound sources include ammonia; ammonium salts such as ammonium sulfate, ammonium nitrate, ammonium carbonate, ammonium chloride, ammonium acetate, ammonium propionate, ammonium malonate, ammonium succinate, ammonium peroxodisulfate, and ammonium copper sulfate; amines such as isopropylamine and t-butylamine; and alkylammonium compounds such as tetramethylammonium hydroxide, tetramethylammonium chloride, isopropylammonium chloride, isopropylamine sulfate, isopropylamine succinate, and t-butylammonium chloride. They may be used solely or in a combination of a plurality of them. Among them, ammonia, ammonium sulfate, ammonium nitrate, ammonium acetate, ammonium propionate, ammonium malonate, ammonium succinate, ammonium peroxodisulfate, tetramethylammonium hydroxide, isopropylamine, and t-butylamine are more preferred. Particularly preferred are ammonia, ammonium sulfate, ammonium nitrate, ammonium acetate, ammonium peroxodisulfate, and tetramethylammonium hydroxide.

Ammonium salts of peroxosulfuric acid such as ammonium peroxodisulfate described above function as the component (C) and also as the peroxosulfate ion source (A). For example, when peroxoammonium sulfate is contained in the liquid composition according to the present invention, the content of the component (C) is the total content of other nitrogen compound sources and ammonium salts of peroxosulfuric acid.

Ammonium copper double salts such as ammonium copper sulfate described above function as the component (C) and also as the copper ion source (B). For example, when ammonium copper sulfate is contained in the liquid composition according to the present invention, the content of the component (C) is the total content of other nitrogen compound sources and the ammonium copper double salt.

Further, ammonium salts of carboxylic acids such as ammonium acetate, ammonium propionate, ammonium malonate, ammonium succinate, and ammonium lactate described above function as the component (C) and also as a carboxylate ion source (D) which will be described later. When ammonium acetate is contained in the liquid composition according to the present invention, the content of the component (C) is the total content of other nitrogen compound sources and the ammonium salt of carboxylic acid.

When hexaammonium molybdate that functions also as a molybdate ion source (E) which will be described later is contained in the liquid composition according to the present invention, the content of the component (C) is the total content of other nitrogen compound sources and ammonium molybdate.

The nitrogen compound source (component (C)) is preferably contained in an amount of 0.05 to 20 moles, more preferably 0.1 to 15 moles, particularly preferably 0.2 to 10 moles, per kg of the liquid composition. The mixing ratio of the nitrogen compound source (component (C)) to the copper ion source (component (B)) is preferably in the range of 4 to 100, more preferably 4 to 80, particularly preferably 4 to 60, on a molar basis. When the content of the nitrogen compound source (component (C)) in the liquid composition according to the present invention is in the above-defined range, precipitate formation does not occur and the etching speed and the sectional shape of the wiring are further improved.

### (D) Carboxvlate Ion Source

The liquid composition according to the present invention may if necessary contain a carboxylate ion source (sometimes hereinafter referred to simply as component (D)). The carboxylate ion source functions as a ligand to copper ions and can improve the stability of the etching liquid composition for a multilayer film containing copper and molybdenum and, at the same time, can stabilize the etching speed. Further, the carboxylate ion source can also suppress the occurrence of a residue that is precipitated in dilution of the liquid composition in the step of rising with water after etching.

Any carboxylate ion source that can supply carboxylate ions can be used as the carboxylate ion source (component (D)) without particular limitation, and examples of preferred carboxylate ion sources include monocarboxylic acids such as formic acid, acetic acid, propionic acid, butyric acid, and isobutyric acid; dicarboxylic acids such as oxalic acid, malonic acid, succinic acid, and maleic acid; aminocarboxylic acids such as glycine and alanine; hydroxycarboxylic acids such as glycolic acid, lactic acid, 2-hydroxyisobutyric acid; and salts of these carboxylic acids. These carboxylate ion sources may be used solely or as a mixture of a plurality of them. Further, since carboxylic anhydrides such as acetic anhydride, propionic anhydride, and maleic anhydride produce carboxylic acids by a reaction with water, carboxylic anhydrides are also suitable as the component (D). Furthermore, since carboxylic esters such as ethyl acetate, propyl acetate, ethyl propionate, dimethyl malonate, diethyl malonate, dimethyl succinate, and diethyl succinate produce carboxylic acids by a hydrolytic reaction r, carboxylic esters are also suitable as the component (D). Among them, acetic acid, propionic acid, malonic acid, succinic acid, lactic acid, and salts of these carboxylic acids, and acetic anhydride are more preferred from the viewpoint of availability. Particularly preferred are acetic acid, acetic anhydride, ammonium acetate, sodium acetate, potassium acetate, and copper acetate.

Ammonium salts of carboxylic acids such as ammonium acetate, ammonium propionate described above function as the component (D) and also as the nitrogen compound source. For example, when the ammonium salt of carboxylic acid is contained in the liquid composition according to the present invention, the content of the component (D) is the total content of other carboxylate ion sources and the ammonium salt of carboxylic acid.

The copper salts of carboxylic acids such as copper acetate function as the component (D) and also as the copper ion source. For example, when the copper salt of carboxylic acid is contained in the liquid composition according to the present invention, the content of the component (D) is the total of other carboxylate ion sources and the copper salt of carboxylic acid.

Carboxylic anhydrides obtained by dehydrocondensing two molecules of carboxylic acids such as acetic anhydride and propionic anhydride produce two molecules of carboxylic acids by a reaction with water Accordingly, when the carboxylic anhydride is contained as the component (D), the amount of twice the content of the carboxylic anhydride is defined as the content of the component (D).

The carboxylate ion source (component (D)) is preferably contained in an amount of 0.001 to 5 moles, more preferably 0.01 to 4 moles, particularly preferably 0.05 to 2 moles, per kg of the liquid composition. The mixing ratio of the carboxylate ion source (component (D)) to the copper ion source (component (B)) is preferably 0.1 to 50, more preferably 0.3 to 40, particularly preferably 0.5 to 30, on a molar basis. When the content of the carboxylate ion source (component (D)) in the liquid composition according to the present invention is in the above-defined range, the etching speed and the sectional shape of the wiring can be further improved. Further, neither residue nor precipitates do not occur after etching.

### (E) Molybdate Ion Source

The liquid composition according to the present invention may if necessary contain a molybdate ion source (sometimes hereinafter referred to simply as component (E)). The molybdate ion source has a function that regulates the etching speed and the etching of the multilayer film containing copper and molybdenum to regulate the sectional shape of the wiring. The liquid composition after use in the etching process disadvantageously has an increased molybdate ion concentration due to the dissolution of molybdenum. Accordingly, when the component (E) is previously contained in the liquid composition, a variation in etching properties (such as etching speed, etching shape, and stability of the liquid composition) can be reduced when the molybdate ion concentration is increased. The incorporation of the molybdate ion source (E) in the liquid composition according to the present invention does not cause the occurrence of bubbles attributable to decomposition of peroxosulfate ions.

Any molybdate ion source that can supply molybdate ions may be used without particular limitation. Any ion species soluble in the liquid composition may be used as the molybdate ions. Examples thereof include orthomolybdate ions that contain one molybdenum atom in the ion, and, further, isopolymolybdate ions such as paramolybdate ions that contain 7 molybdenum atoms in the ion, and heteropolymolybdate ions that contain a hetero element in the ion. Examples of preferred molybdate ion sources include molybdenum and, further, molybdates such as ammonium molybdate, sodium molybdate, and potassium molybdate; heteropolymolybdates such as ammonium phosphomolybdate and ammonium silicomolybdate; oxides or hydroxides such as molybdenum oxide and molybdenum blue; and molybdenum sulfide. These molybdate ion sources may be used solely or in a combination of a plurality of them. Among them, molybdenum, ammonium molybdate, sodium molybdate, potassium molybdate, and molybdenum oxide are more preferred, and molybdenum, ammonium molybdate, and molybdenum oxide are particularly preferred.

Ammonium salts such as ammonium molybdate function as the component (E) and also as the nitrogen compound source.

The content of the molybdate ion source (component (E)) in the liquid composition according to the present invention is calculated in terms of the content of orthomolybdate ions that contain one molybdenum in the ion. For example, when hexaammonium molybdate that contains 7 molybdenum atoms in the ion is used as the molybdate ion source (component (E)), the content of the molybdate ion source (component (E)) is an amount of 7 times the content of hexaammonium molybdate.

The molybdate ion source (component (E)) is preferably contained in an amount of 1×10⁻⁶ to 5×10⁻² mole, more preferably 1×10⁻⁵ to 2×10⁻² mole, particularly preferably 1×10⁻⁴ to 1×10⁻² mole, in terms of orthomolybdate ions per kg of the liquid composition. When the content of the molybdate ion source (component (E)) in the liquid composition according to the present invention is in the above-defined range, the etching speed and the sectional shape of the wiring can be further improved. Further, a variation in etching properties attributable to the dissolution of copper and molybdenum can be reduced by adding the molybdate ion source (component (E)) so that the mixing ratio of the molybdate ion source (component (E)) to the copper ion source (component (B)) on a molar basis is approximately the same as the molar ratio between copper ions and molybdate ions that are dissolved in the liquid composition in the etching process.

The liquid composition according to the present invention should have pH 3.5 to 9. When the liquid composition is in the above-defined pH range, the sectional shape of the wiring is improved. Further, the nitrogen compound is less likely to be volatilized from the liquid composition. Thus, the stability of the liquid composition and the working environment in the etching process can be maintained. When pH is below 3.5, the CD loss is disadvantageously likely to be increased. On the other hand, when pH is above 9, the taper angle and the CD loss are disadvantageously likely to be increased. Further, an ammoniacal odor derived from the component (C) is emitted. Preferably, the liquid composition has pH 4 to 8.

### (F) pH Adjustor

The liquid composition according to the present invention may if necessary contain a pH adjustor (sometime hereinafter referred to simply as component (F)) for pH adjustment purposes. Any pH adjustor that does not hinder the effect of the liquid composition may be used as the pH adjustor (component (F)), and examples of preferred pH adjustors include ammonia and metal hydroxides such as sodium hydroxide and potassium hydroxide; amines such as isopropylamine and t-butylamine; hydroxylamines such as hydroxylamine; alkanolamines such as monoethanolamine, diethanolamine, and triethanolamine; alkylammonium compounds such as tetramethylammonium hydroxide; inorganic acids such as hydrochloric acid, sulfuric acid, and nitric acid; and organic acids such as acetic acid, propionic acid, malonic acid, succinic acid, and lactic acid. These pH adjustors may be used either solely or in a combination of a plurality of them. Among them, ammonia, potassium hydroxide, isopropylamine, t-butylamine, tetramethylammonium hydroxide, sulfuric acid, acetic acid, propionic acid, malonic acid, succinic acid, and lactic acid are more preferred.

The content of the pH adjustor in the liquid composition according to the present invention is properly determined depending upon the content of other components so that the liquid composition has pH 3.5 to 9

The liquid composition according to the present invention may contain, in addition to the components (A) to (C) and optional components (D) to (F), water and other various additives commonly used in etching liquid compositions in such an amount that the effect of the liquid composition is not sacrificed. Examples thereof include chelating agents, pH buffers, and radical scavengers that are effective as stabilizers for peroxosulfate ions. Water from which metal ions, organic impurities, particulate particles and the like have been removed, for example, by distillation, ion exchange treatment, filter treatment, or various adsorption treatments is preferred. Pure water is more preferred, and ultrapure water is particularly preferred.

### <Etching Method for Multilayer Film Containing Copper and Molybdenum>

The etching method according to the present invention is an etching method for a multilayer film containing copper and molybdenum, the etching method including bringing the above liquid composition into contact with the above multilayer film. According to the method of the present invention, the multilayer film containing copper and molybdenum can be etched at one time, and, further, the occurrence of etching residue and precipitates can be prevented. Further, according to the present invention, as described above, a sectional shape of the multilayer film wiring that has a taper angle of 15 to 75 degrees and a bottom CD loss of not more than 2.5 μm can be obtained. Further, the etching speed is substantially constant regardless of the flow rate distribution of the liquid composition, and, thus, the etching can be evenly carried out at all of sites in the substrate.

In the etching method according to the present invention, the multilayer film containing copper and molybdenum is an etching object. In the present invention, the multilayer film as the etching object has a multilayer structure of a layer of copper or a compound composed mainly of copper and a layer of molybdenum or a compound composed mainly of molybdenum. Examples of multilayer films include a multilayer film having a two-layer structure composed of a layer of copper or a compound composed mainly of copper and a layer of molybdenum or a compound composed mainly of molybdenum that are stacked on each other and a multilayer film having a three-layer structure consisting of a layer of molybdenum or a compound composed mainly of molybdenum, a layer of copper or a compound composed mainly of copper, and a layer of molybdenum or a compound composed mainly of molybdenum that are stacked in that order. A multilayer film having a three-layer structure consisting of a layer of molybdenum or a compound composed mainly of molybdenum, a layer of copper or a compound composed mainly of copper, and a layer of molybdenum or a compound composed mainly of molybdenum that are stacked in that order is particularly preferred from the viewpoint of effectively exerting the properties of the liquid composition according to the present invention.

Examples of copper or compounds composed mainly of copper include copper (metal), copper alloys, copper oxide and copper nitride. Examples of molybdenum or compounds composed mainly of molybdenum include molybdenum (metal), molybdenum alloys, and oxides or nitrides thereof.

The etching object can be obtained by stacking a layer of molybdenum, a layer of copper, and a layer of molybdenum in that order on a substrate such as glass to form a three-layer film as a multilayer film, coating a resist on the three-layer film, subjecting the resist to exposure and transfer of a desired pattern mask, and then performing development to form a desired resist pattern. Examples of substrates on which the multilayer film may be formed include, in addition to the glass substrate, a substrate having a layer construction obtained by forming a gate wiring on a glass substrate and providing an insulating film formed of silicon nitride or the like on the gate wiring. In the present invention, a multilayer film wiring including a multilayer film, the multilayer film including a molybdenum-containing layer and a copper-containing layer, can be obtained by bringing the etching object into contact with the liquid composition to etch the multilayer film to form a desired multilayer film wiring. The wiring of the multilayer film containing copper and molybdenum is preferred for use, for example, in wiring of display devices such as flat panel displays.

The liquid composition can be brought into contact with the etching object by any method without particular limitation. For example, a wet etching method may be adopted, and examples thereof include a method in which the liquid composition is brought into contact with the object, for example, by dropping of the liquid composition (sheet spinning) or spraying, and a method in which the etching object is immersed in the liquid composition. In the present invention, even etching can be achieved by any method. A method in which the liquid composition is brought into contact with the etching object by spraying is especially preferred. Downward spraying of the liquid composition from above the etching object, or upward spraying of the liquid composition from below the etching object may be used in the method in which the liquid composition is brought into contact with the object by spraying. In this case, the spray nozzle may be fixed or alternatively may have such a structure that oscillating or sliding motion is possible. Further, the spray nozzle may be installed vertically downward or alternatively may be installed in an inclined state. The etching object may be installed horizontally or alternatively may be installed in an inclined state.

The service temperature of the liquid composition is preferably 10 to 70° C., particularly preferably 20 to 50° C. When the temperature of the liquid composition is 10° C. or above, the etching speed is so good that a high production efficiency can be obtained. On the other hand, when the temperature of the liquid composition is 70° C. or below, a change in liquid formulation can be suppressed and etching conditions can be kept constant. When the temperature of the liquid composition is raised, the etching speed is increased. However, an optimal treatment temperature may be properly determined by taking into consideration, for example, minimization of a change in formulation of the liquid composition.

### EXAMPLES

The present invention is further illustrated by the following Examples that are not intended as a limitation of the invention.

### <Evaluation of Sectional Form of Multilayer Wiring After Etching>

The sectional shape of the wiring of multilayer thin-film samples that include a copper layer and a molybdenum layer after etching and had been obtained in Examples and Comparative Examples was observed under a scanning electron microscope (“55000H type (model number)”; manufactured by Hitachi, Ltd.) at a magnification of 30000 times (accelerating voltage, 2 kV, emission current 10 μA). SEM images thus obtained were evaluated as acceptable when the shape was a forward tapered one, of which the taper angle of the sectional shape of the wiring was 15 to 75 degrees, and the bottom CD loss was not more than 2.5 μm.

### Reference Example 1

### Preparation of Molybdenum/Copper/Molybdenum/Glass Substrate

Molybdenum was sputtered on a glass substrate (dimension: 150 mm×150 mm) to form a layer of molybdenum (metal) (molybdenum layer thickness: 200 angstroms). Subsequently, copper was sputtered to form a layer of copper (metal) (copper layer thickness: 5000 angstroms). Molybdenum was again sputtered to form a layer of molybdenum (metal) (molybdenum layer thickness: 200 angstroms) to form a three-layer film structure of molybdenum/copper/molybdenum. Further, a resist was coated. The resist was subjected to exposure and transfer of a line pattern mask (line width: 20 μm), followed by development to prepare a molybdenum/copper/molybdenum/glass substrate with a resist pattern formed thereon.

### Reference Example 2

### Preparation of Copper/Molybdenum/Glass Substrate

Molybdenum was sputtered on a glass substrate (dimension: 150 mm ×150 mm) to form a layer of molybdenum (metal) (molybdenum layer thickness: 200 angstroms). Copper was then sputtered to form a layer of copper (metal) (copper layer thickness: 5000 angstroms) and thus to form a two-layer film structure of copper/molybdenum. Further, a resist was coated. The resist was subjected to exposure and transfer of a line pattern mask (line width: 20 μm), followed by development to prepare a copper/molybdenum/glass substrate with a resist pattern formed thereon.

### Example 1

Pure water (8.69 kg), 0.20 kg of ammonium peroxodisulfate (manufactured by Mitsubishi Gas Chemical Co., Ltd., molecular weight 228.2) that is a peroxosulfate ion source (A) and also a member belonging to a component (C), 0.31 kg of copper sulfate pentahydrate (manufactured by Wako Pure Chemical Industries, Ltd., guaranteed grade, molecular weight 249.7) as a copper ion source (B), and 0.50 kg of ammonium sulfate (manufactured by Wako Pure Chemical Industries, Ltd., guaranteed grade, molecular weight 132.1) as a member belonging to a nitrogen compound source (C) were introduced into a 10 L-volume polypropylene container. The mixture was stirred, and, after the dissolution of the components was confirmed, 0.30 kg of an aqueous ammonia solution (concentration: 28% by weight, manufactured by Mitsubishi Gas Chemical Co., Ltd.) that is a pH adjustor (F) and also a member belonging to the component (C) was added thereto. The mixture was again stirred to prepare a liquid composition.

The content of the components in the liquid composition thus obtained per kg of the liquid composition was 0.09 mole for the component (A) and 0.13 mole for the component (B). The mixing ratio (molar ratio) of the component (A) to the component (B) was 0.7. The content of the component (C) per kg of the liquid composition was 1.43 moles in terms of the total of twice the content (0.09 mole) of ammonium peroxodisulfate, twice the content (0.38 mole) of ammonium sulfate, and the content (0.50 mole) of the aqueous ammonia solution. The mixing ratio (molar ratio) of the component (C) to the component (B) was 11.4. The liquid composition thus obtained had pH 8.0.

This liquid composition was sprayed at 35° C. with a small etching machine (manufactured by Kanto Kikai Kogyo K.K.) on the molybdenum/copper/molybdenum/glass substrate with the resist pattern formed thereon obtained in Reference Example 1. The molybdenum/copper/molybdenum/glass substrate was placed horizontally so that the film formed surface faced upward (with the position fixed and not swung), and a spray nozzle was fixed downward vertically (with not oscillated). The spray nozzle used was a nozzle that sprays a liquid not uniformly but at a distributed flow rate (a nozzle that exhibits a circular spray pattern and a flow rate distribution that the flow rate is large at a center of a circle just under the nozzle and is small at a peripheral portion).

The time taken until the molybdenum/copper/molybdenum laminated film at its portion not covered with the resist disappeared and, consequently, the transparent glass substrate was exposed was found to be 55 sec by visual observation. The time taken until the transparent glass substrate was exposed at the whole area in the substrate was 61 sec. After etching for 83 sec (under 50% overetching conditions), the molybdenum/copper/molybdenum/glass substrate was rinsed and was then dried with a blower, and was observed under an optical microscope. As a result, it was confirmed that the molybdenum/copper/molybdenum laminated film at its exposed areas, that is, areas other than areas covered with the patterned resist, was completely removed, and no etching residue was observed on the glass substrate. However, a very small amount of precipitates occurred when rinsing was carried out with water. When rising was carried out with an aqueous citric acid solution (concentration: 1% by weight) (at room temperature for one min), no precipitates were observed on the glass substrate.

After the etching treatment, the molybdenum/copper/molybdenum/glass substrate was broken, and the cross section of the substrate was observed under a scanning secondary electron microscope. As a result, it was found that the angle (taper angle) of the etching surface at the end of the wiring that makes with the underlying substrate was 20 degrees, that is, the shape was a forward tapered one, and the horizontal distance from the end of the lower layer (bottom) of the wiring to the end of the resist, that is, bottom CD loss, was 1.0 μm. The evaluation results were as shown in Table 1 below. In Table 1, the contents of the components in the liquid composition are in number of moles per kg of the liquid composition. The bottom CD loss values are values measured under 50% overetching conditions. A secondary electron microscopic image obtained in Example 1 is shown in FIG. 2.

### Example 2

A liquid composition was prepared in the same manner as in Example 1, except that the amount of ammonium sulfate incorporated as a member belonging to the nitrogen compound source (C) was changed to 1.00 kg, the amount of the aqueous ammonia solution (concentration: 28% by weight) incorporated that is a pH adjustor (F) and a member belonging to the component (C) was changed to 0.03 kg, and the liquid composition had a formulation shown in Table 1 below. The content of the component (C) per kg of the liquid composition was 1.73 moles in terms of the total of twice the content (0.09 mole) of ammonium peroxodisulfate, twice the content (0.76 mole) of ammonium sulfate, and the content (0.04 mole) of the aqueous ammonia solution. The liquid composition thus obtained had pH 5.0.

This liquid composition was sprayed (under 50% overetching conditions). The just etching time was 47 sec, and the transparent glass substrate was exposed in the whole area in the substrate at one time. After etching for 71 sec (under 50% overetching conditions), the molybdenum/copper/molybdenum/glass substrate was rinsed with an aqueous citric acid solution. As a result, neither etching residue nor precipitates were observed. The cross section of the substrate was observed under a scanning secondary electron microscope. As a result, it was found that the shape was a forward tapered one with a taper angle of 70 degrees and the bottom CD loss was 1.5 μm. The evaluation results were as shown in Table 1 below.

### Examples 3 to 5

A liquid composition was prepared in the same manner as in Example 1, except that methanesulfonic acid was added as a stabilizer for peroxosulfate ions in an amount of 0.01 mole per kg of the liquid composition, the content of ammonium peroxodisulfate (manufactured by Mitsubishi Gas Chemical Co., Ltd., molecular weight 228.2) that is a peroxosulfate ion source (A) and also a member belonging to a component (C) was changed to 0.20 kg (Example 3), 0.50 kg (Example 4), and 0.01 kg (Example 5), and the liquid composition had a formulation shown in Table 1 below. Spraying (under 50% overetching conditions) was carried out in the same manner as in Example 1, except that the liquid composition obtained just above was used. For all the substrates, neither etching residue nor precipitates were observed. The cross section of the substrates was observed under a scanning secondary electron microscope. As a result, both the taper angle and the bottom CD loss were good. The evaluation results were as shown in Table 1 below.

### Examples 6 and 7

A liquid composition was prepared in the same manner as in Example 1, except that methanesulfonic acid was added as a stabilizer for peroxosulfate ions in an amount of 0.01 mole per kg of the liquid composition, the content of ammonium sulfate that is a member belonging to the nitrogen compound source (C) was changed to 0.30 kg (Example 6) and 1.00 kg (Example 7), and the liquid composition had a formulation shown in Table 1 below. Spraying (under 50% overetching conditions) was carried out in the same manner as in Example 1, except that the liquid composition obtained just above was used. For both the substrates, neither etching residue nor precipitates were observed. The cross section of the substrates was observed under a scanning secondary electron microscope. As a result, both the taper angle and the bottom CD loss were good. The evaluation results were as shown in Table 1 below.

### Example 8

A liquid composition was prepared in the same manner as in Example 1, except that 0.20 kg of sodium peroxodisulfate (manufactured by Mitsubishi Gas Chemical Co., Ltd., molecular weight 238.1) was used as the component (A) instead of ammonium peroxodisulfate, 0.01 mole, per kg of the liquid composition, of methanesulfonic acid was added as a stabilizer for peroxosulfate ions, and the liquid composition had a formulation shown in Table 1 below. Spraying (under 50% overetching conditions) was carried out in the same manner as in Example 1, except that the liquid composition obtained just above was used. Neither etching residue nor precipitates were observed. Both the taper angle and the bottom CD loss were good. The evaluation results were as shown in Table 1 below.

### Example 9

A liquid composition was prepared in the same manner as in Example 1, except that hexaammonium molybdate tetrahydrate that is a molybdate ion source (E) was added as other component in an amount of 0.003 mole in terms of orthomolybdate ions per kg of the liquid composition, and the liquid composition had a formulation shown in Table 1 below. Spraying (under 50% overetching conditions) was carried out in the same manner as in Example 1, except that the liquid composition obtained just above was used. Neither etching residue nor precipitates were observed, and both the taper angle and the bottom CD loss were good. A secondary electron microscopic image is shown in Table 3. The evaluation results were as shown in Table 1 below. In Table 1, the content of the molybdate ion source was calculated as an amount of 7 times the content of hexaammonium molybdate (4×10⁻⁴ moles) per kg of the liquid composition.

### Example 10

In the same manner as in Example 1, the liquid composition prepared in Example 9 was sprayed on the copper/molybdenum/glass substrate with the resist pattern formed thereon prepared in Reference Example 2. The time taken until the transparent substrate was exposed (just etching time) was 50 sec, and the time taken until the transparent glass substrate was exposed at the whole area in the substrate was 55 sec. After etching for 75 sec (under 50% overetching conditions), the copper/molybdenum/glass substrate was rinsed with an aqueous citric acid solution (concentration; 1% by weight) (at room temperature for one min) and was then dried with a blower and was observed under an optical microscope. As a result, it was confirmed that the copper/molybdenum laminated film at its exposed areas, that is, areas other than areas covered with the patterned resist, was completely removed, and neither etching residue nor precipitates were observed on the glass substrate. After the etching treatment, the copper/molybdenum/glass substrate was broken, and the cross section of the substrate was observed under a scanning secondary electron microscope. As a result, it was found that the shape was a forward tapered one with a taper angle of 60 degrees, and the bottom CD loss was 0.6 μm. The evaluation results were as shown in Table 1 below.

TABLE 1

| Components of liquid composition | | | | | | | | | Exam- | Exam- | Exam- |
|---|---|---|---|---|---|---|---|---|---|---|---|
| (mol/kg) | | Example 1 | Example 2 | Example 3 | Example 4 | Example 5 | Example 6 | Example 7 | ple 8 | ple 9 | ple 10 |
| Component A | Ammonium | 0.09 | 0.09 | 0.09 | 0.22 | 0.004 | 0.09 | 0.09 | — | 0.09 | 0.09 |
| | peraxodisulfate | | | | | | | | | | |
| | Sodium | — | — | | — | — | — | — | 0.08 | — | — |
| | peroxodisulfate | | | | | | | | | | |
| Component B | | 0.13 | 0.13 | 0.13 | 0.13 | 0.13 | 0.13 | 0.13 | 0.13 | 0.13 | 0.13 |
| Component C | | 1.43 | 1.73 | 1.46 | 1.75 | 1.26 | 1.09 | 2.20 | 1.44 | 1.43 | 1.43 |
| Other | Methanesulfonic | — | — | 0.01 | 0.01 | 0.01 | 0.01 | 0.01 | 0.01 | — | — |
| components | acid | | | | | | | | | | |
| | Hexaammonium | — | — | — | — | — | — | — | — | 0.003 | 0.003 |
| | molybdate (×7) | | | | | | | | | | |

| | | | | | | | | | | |
|---|---|---|---|---|---|---|---|---|---|---|
| Component A/ | 0.7 | 0.7 | 0.7 | 1.8 | 0.03 | 0.7 | 0.7 | 0.7 | 0.7 | 0.7 |
| Component B molar ratio | | | | | | | | | | |
| Component C/ | 11.4 | 13.8 | 11.7 | 13.9 | 10.0 | 8.7 | 17.6 | 11.5 | 11.4 | 11.4 |
| component B molar ratio | | | | | | | | | | |
| Layer structure of etching object | Three- | Three- | Three- | Three- | Three- | Three- | Three- | Three- | Three- | Two- |
| | layer | layer | layer | layer | layer | layer | layer | layer | layer | layer |
| | structure | structure | structure | structure | structure | structure | structure | struc- | struc- | struc- |
| | | | | | | | | ture | ture- | ture |
| pH of liquid composition | 8.0 | 5.0 | 8.0 | 8.0 | 8.0 | 8.0 | 8.0 | 8.0 | 8.0 | 8.0 |
| Just etching time (sec) | 55-61 | 47 | 63-69 | 60-64 | 30-38 | 123-130 | 33-35 | 59-66 | 50-61 | 50-55 |
| Taper angle (degree) | 20 | 70 | 20 | 20 | 50 | 20 | 60 | 20 | 40 | 60 |
| Bottom CD loss (μm) | 1.0 | 1.5 | 1.1 | 1.5 | 1.0 | 1.2 | 1.2 | 1.0 | 0.8 | 0.6 |

### Comparative Example 1

A liquid composition was prepared in the same manner as in Example 1, except that the peroxosulfate ion source (A) was not added and the liquid composition had a formulation shown in Table 2 below. Spraying (under 50% overetching conditions) was carried out in the same manner as in Example 1, except that the liquid composition obtained just above was used. In Comparative Example 1 where the peroxosulfate ion source (A) was not contained, the taper angle was not less than 90 degrees although the just etching time was 25 sec and the time taken until the transparent glass substrate was exposed in the whole area in the substrate was exposed was 33 sec. The evaluation results were as shown in Table 2 below. A secondary electron microscopic image in Comparative Example 1 is shown in FIG. 4.

### Comparative Example 2

A liquid composition was prepared in the same manner as in Example 1, except that the copper ion source (B) was not added and the liquid composition had a formulation shown in Table 2 below. Spraying (under 50% overetching conditions) was carried out in the same manner as in Example 1, except that the liquid composition obtained just above was used. In Comparative Example 2 where the copper ion source (B) was not contained, the just etching time was 57 sec, and, although the transparent glass substrate was exposed in the whole area in the substrate at one time, the taper angle and the bottom CD loss were 90 degrees and 2.1 μm, respectively. The evaluation results were as shown in Table 2 below.

### Comparative Example 3

A liquid composition was prepared in the same manner as in Example 1, except that the aqueous ammonia solution that is the pH adjustor (F) and also a member belonging to the component (C) was not added and the liquid composition had a formulation shown in Table 2 below. The liquid composition thus obtained had pH 3.3. Spraying (under 50% overetching conditions) was carried out in the same manner as in Example 1, except that the liquid composition obtained just above was used. In Comparative Example 3 where pH was lowered, the just etching time was 62 sec, and, although the transparent glass substrate was exposed in the whole area in the substrate, the bottom CD loss was not less than 3.0 μm. The evaluation results were as shown in Table 2 below.

TABLE 2

| Components of liquid composition | | Comparative | Comparative | Comparative |
|---|---|---|---|---|
| (mol/kg) | | Example 1 | Example 2 | Example 3 |
| Component A | | — | 0.09 | 0.09 |
| (Ammonium peroxodisulfate) | | | | |
| Component B | | 0.13 | — | 0.13 |
| Component C | | 1.24 | 0.99 | 1.69 |
| Other components | Methanesulfonic | — | — | — |
| | acid | | | |
| | Hexaammonium | — | — | — |
| | molybdate(×7) | | | |

| | | | |
|---|---|---|---|
| Component A/Component B molar ratio | — | — | 0.7 |
| Component C/component B molar ratio | 9.9 | — | 13.5 |
| Layer structure of etching object | Three-layer | Three-layer | Three-layer |
| | structure | structure | structure |
| pH of liquid composition | 8.0 | 8.0 | 3.3 |
| Just etching time (sec) | 25-33 | 57 | 62 |
| Taper angle (degree) | 90 or more | 90 | 40 |
| Bottom CD loss (μm) | 1.5 | 2.1 | 3.0 or more |

### Example 11

Pure water (8.89 kg), 0.20 kg of ammonium peroxodisulfate (manufactured by Mitsubishi Gas Chemical Co., Ltd., molecular weight 228.2) that is a peroxosulfate ion source (A) and also a member belonging to a component (C), 0.31 kg of copper sulfate pentahydrate (manufactured by Wako Pure Chemical Industries, Ltd., guaranteed grade, molecular weight 249.7) as a copper ion source (B), and 0.30 kg of ammonium acetate (manufactured by Wako Pure Chemical Industries, Ltd., guaranteed grade, molecular weight 77.1) that is a member belonging to the component (C) and also a carboxylate ion source (D) were introduced into a 10 L-volume polypropylene container. The mixture was stirred, and, after the dissolution of the components was confirmed, 0.30 kg of an aqueous ammonia solution (concentration: 28% by weight, manufactured by Mitsubishi Gas Chemical Co., Ltd.) that is a pH adjustor (F) and also a member belonging to the component (C) was added thereto. The mixture was again stirred to prepare a liquid composition.

The content of the components in the liquid composition thus obtained per kg of the liquid composition was 0.09 mole for the component (A) and 0.13 mole for the component (B). The mixing ratio (molar ratio) of the component (A) to the component (B) was 0.7. The content of the component (C) per kg of the liquid composition was 1.05 moles in terms of the total of twice the content (0.09 mole) of ammonium peroxodisulfate, the content (0.39 mole) of ammonium acetate incorporated, and the content (0.50 mole) of the aqueous ammonia solution. The mixing ratio (molar ratio) of the component (C) to the component (B) was 8.4. The content of the component (D) per kg of the liquid composition was 0.39 mole, and the mixing ratio (molar ratio) of the component (D) to the component (B) was 3.1 moles. The liquid composition thus obtained had pH 8.0.

This liquid composition was sprayed on the molybdenum/copper/molybdenum/glass substrate with the resist pattern formed thereon obtained in Reference Example 1 in the same manner as in Example 1. The just etching time was 74 sec, and the transparent glass substrate at its whole area in the substrate was exposed at one time. After etching for 111 sec (under 50% overetching conditions), the molybdenum/copper/molybdenum/glass substrate was rinsed with water. As a result, it was confirmed that neither etching residue nor precipitates were observed on the glass substrate. In the liquid composition of Example 11 that contained the component (D), the precipitation of residue in dilution with water was suppressed, and, thus, rising with an aqueous citric acid solution was not necessary.

The molybdenum/copper/molybdenum/glass substrate after etching was broken, and the cross section of the substrate was observed under a scanning secondary electron microscope. As a result, the shape was a forward tapered one with a taper angle of 60 degrees, and the bottom CD loss was 2.0 μm. The evaluation results were as shown in Table 3 below.

### Comparative Example 4

A liquid composition was prepared in the same manner as in Example 11, except that the peroxosulfate ion source (A) was not added and the liquid composition had a formulation shown in Table 3 below. Spraying was carried out in the same manner as in Example 11, except that the liquid composition obtained just above was used. In Comparative Example 4 where the peroxosulfate ion source (A) was not contained, the just etching time was long and 315 sec, and, after etching for 475 sec (under 50% overetching conditions), at the peripheral portion of the substrate, the molybdenum/copper/molybdenum laminated film at its exposed areas, that is, areas other than areas covered with the patterned resist, did not completely disappear, indicating that etching was not even. At the center of the substrate where etching proceeded, the cross section of a broken substrate was observed under a scanning secondary electron microscope. As a result, the taper angle was 80 degrees. The evaluation results were as shown in Table 3 below.

### Examples 12 to 14

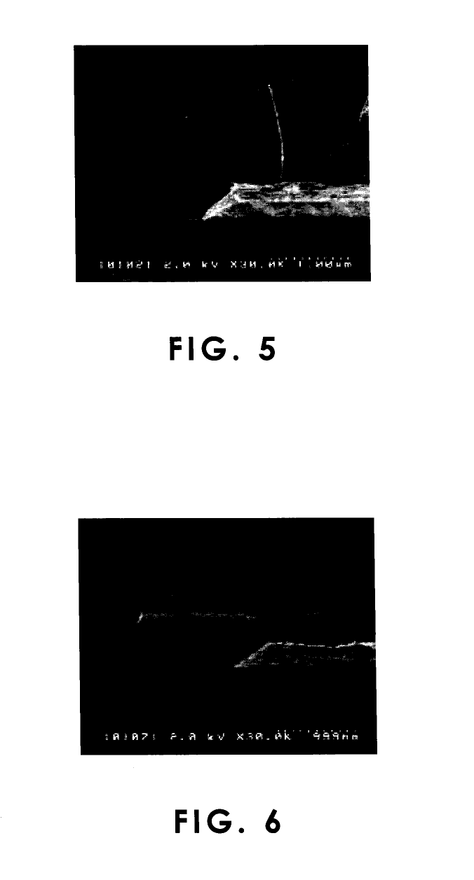

Liquid compositions were prepared in the same manner as in Example 11, except that the liquid compositions had formulations shown in Table 3 below. Spraying (under 50% overetching conditions) was carried out in the same manner as in Example 11, except that the liquid compositions obtained just above were used. For all the liquid compositions, at the whole area in the substrate, the transparent glass substrate was exposed at one time. Neither etching residue nor precipitates were observed, and both the taper angle and the bottom CD loss were also good. A secondary electron microscopic image of Example 13 is shown as one example in FIG. 5. The evaluation results were as shown in Table 3 below.

### Example 15

A liquid composition was prepared in the same manner as in Example 11, except that sodium peroxodisulfate was used instead of ammonium peroxodisulfate as the component (A) and the liquid compositions had a formulation shown in Table 3 below. Spraying (under 50% overetching conditions) was carried out in the same manner as in Example 11, except that the liquid composition obtained just above was used. Neither etching residue nor precipitates were observed, and both the taper angle and the bottom CD loss were also good. The evaluation results were as shown in Table 3 below.

### Example 16

A liquid composition was prepared in the same manner as in Example 11, except that the liquid composition had a formulation shown in Table 3 below. Spraying (under 50% overetching conditions) was carried out in the same manner as in Example 11, except that the liquid composition obtained just above was used. As a result, at the whole area in the substrate, the transparent glass substrate was exposed at one time. Neither etching residue nor precipitates were observed, and both the taper angle and the bottom CD loss were also good. In Table 3, the content of the molybdate ion source was calculated as an amount of 7 times the content of hexaammonium molybdate (4×10⁻⁴ moles) in terms of orthomolybdate ions per kg of the liquid composition.

### Comparative Example 5

A liquid composition was prepared in the same manner as in Example 11, except that the liquid composition had a formulation shown in Table 3 below. The liquid composition had pH 10.0. Spraying (under 50% overetching conditions) was carried out in the same manner as in Example 11, except that the liquid composition obtained just above was used. In the liquid composition of Comparative Example 5 where pH was increased, the just etching time was short and 4 sec and, at the whole area in the substrate, the transparent glass substrate was exposed at one time. However, the taper angle and the bottom CD loss were not less than 90 degrees and not less than 3.0 μm, respectively.

Further, an odor of ammonia was emitted during etching. The evaluation results were as shown in Table 3 below.

TABLE 3

| Components of liquid composition | | Example | Example | Example | Example | Example | Example | Comparative | Comparative |
|---|---|---|---|---|---|---|---|---|---|
| (mol/kg) | | 11 | 12 | 13 | 14 | 15 | 16 | Example 4 | Example 5 |
| Component A | Ammonium peroxodisulfate | 0.09 | 0.09 | 0.09 | 0.09 | — | 0.09 | — | 0.09 |
| | Sodium peroxodisulfate | — | — | — | — | 0.09 | — | — | — |
| Component B | | 0.13 | 0.13 | 0.13 | 0.13 | 0.13 | 0.13 | 0.13 | 0.13 |
| Component C | | 1.05 | 1.02 | 0.56 | 0.56 | 0.57 | 0.57 | 0.78 | 1.61 |
| Component D (ammonium acetate) | | 0.39 | 0.78 | 0.39 | 0.39 | 0.57 | 0.39 | 0.78 | 0.39 |
| Other | Methanesulfonic acid | — | — | — | 0.03 | 0.03 | — | — | — |
| components | Hexaammonium molybdate (×7) | — | — | — | — | — | 0.003 | 0.003 | — |
| | Sulfuric acid | — | — | 0.02 | 0.01 | 0.03 | 0.06 | 0.07 | — |

| | | | | | | | | |
|---|---|---|---|---|---|---|---|---|
| Component A/Component B molar ratio | 0.7 | 0.7 | 0.7 | 0.7 | 0.7 | 0.7 | — | 0.7 |
| Component C/component B molar ratio | 8.4 | 8.1 | 4.5 | 4.5 | 4.6 | 4.5 | 6.2 | 17.3 |
| Component D/Component B molar ratio | 3.1 | 6.2 | 3.1 | 3.1 | 4.6 | 3.1 | 6.2 | 3.1 |
| Layer structure of etching object | Three- | Three- | Three- | Three- | Three- | Three- | Three-layer | Three-layer |
| | layer | layer | layer | layer | layer | layer | structure | structure |
| | structure | structure | structure | structure | structure | structure | | |
| pH of liquid composition | 8.0 | 6.0 | 5.0 | 5.0 | 5.0 | 4.5 | 5.0 | 10.0 |
| Just etching time (sec) | 74 | 119 | 78 | 75 | 97 | 93 | 315 | 4 |
| Taper angle (degree) | 60 | 25 | 45 | 45 | 45 | 55 | 80 | 110 |
| Bottom CD loss (μm) | 2.0 | 1.3 | 1.1 | 1.1 | 1.2 | 2.0 | 1.5 | 6.4 |

### Examples 17 to 20

Liquid compositions were prepared in the same manner as in Example 11, except that acetic acid, sodium acetate, acetic anhydride, or propionic acid was used instead of ammonium acetate as the component (D) and the liquid compositions had formulations shown in Table 4 below. Spraying (under 50% overetching conditions) was carried out in the same manner as in Example 11, except that the liquid compositions obtained just above were used. For all the liquid compositions, at the whole area in the substrate, the transparent glass substrate was exposed at one time. Neither etching residue nor precipitates were observed, and both the taper angle and the bottom CD loss were also good. The evaluation results were as shown in Table 4 below. A secondary electron microscopic image of Example 17 is shown as one example in FIG. 6. In Table 4, the content of acetic anhydride was calculated as an amount of twice the content (0.39 mole) of acetic anhydride in terms of acetate ions per kg of the liquid composition. The content of the molybdate ion source was calculated as an amount of 7 times the content of hexaammonium molybdate in terms of orthomolybdate ions per kg of the liquid composition.

### Examples 21

A liquid composition was prepared in the same manner as in Example 11, except that the liquid composition had a formulation shown in Table 4 below. Spraying (under 50% overetching conditions) was carried out in the same manner as in Example 11, except that the liquid composition obtained just above was used. The just etching time was 26 sec, and the time taken until the transparent substrate was exposed at all the areas in the substrate was 30 sec. The molybdenum/copper/molybdenum/glass substrate after etching for 39 sec (under 50% overetching conditions) was rinsed with water. As a result, neither etching residue nor precipitates were confirmed, and both the taper angle and the bottom CD loss were also good. The evaluation results were as shown in Table 4 below.

### Examples 22 to 24

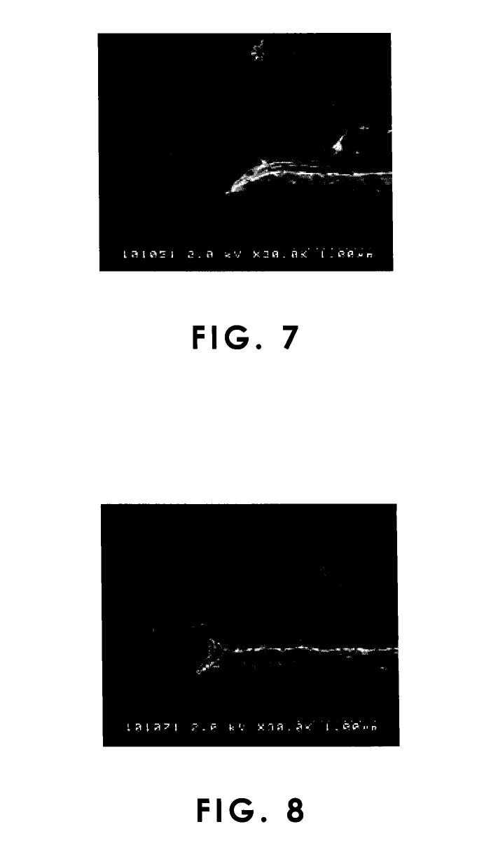

Liquid compositions were prepared in the same manner as in Example 11, except that succinic acid, lactic acid, or malonic acid was added as a member belonging to the component (D) and had formulations shown in Table 4 below. Spraying (under 50% overetching conditions) was carried out in the same manner as in Example 11, except that the liquid compositions obtained just above were used. For all the liquid compositions, neither etching residue nor precipitates were observed, and both the taper angle and the bottom CD loss were also good. The evaluation results were as shown in Table 4 below. A secondary electron microscopic image of Example 22 is shown as one example in FIG. 7.

### Example 25

A liquid composition was prepared in the same manner as in Example 11, except that 2-hydroxyisobutyric acid was added as a member belonging to the component (D) and the liquid composition had a formulation shown in Table 4 below. Spraying was carried out on the copper/molybdenum/glass substrate with the resist pattern formed therein obtained in Reference Example 2 in the same manner as in Example 1, except that the liquid composition obtained just above was used. The time taken until the transparent glass substrate was exposed (just etching time) was 40 sec, and the time taken until the transparent substrate was exposed at all the areas in the substrate was 43 sec. After etching for 60 sec (under 50% overetching conditions), the copper/molybdenum/glass substrate was rinsed with water, was dried with a blower, and the dried substrate was observed under an optical microscope. As a result, it was confirmed that the copper/molybdenum laminated film at its exposed areas, that is, areas other than areas covered with the patterned resist, was completely removed, and neither etching residue nor precipitates were observed on the glass substrate. After the etching treatment, the copper/molybdenum/glass substrate was broken, and the cross section of the substrate was observed under a scanning secondary electron microscope. As a result, it was found that the shape was a forward tapered one with a taper angle of 60 degrees, and the bottom CD loss was 0.5 μm. The evaluation results were as shown in Table 4 below. A secondary electron microscopic image in Example 25 is shown in FIG. 8.

TABLE 4

| Component A | | Example | Example | Example | Example | Example | Example | Example | Example | Example |
|---|---|---|---|---|---|---|---|---|---|---|
| (ammonium peroxodisulfate) | | 17 | 18 | 19 | 20 | 21 | 22 | 23 | 24 | 25 |
| Components of liquid composition | | 0.09 | 0.09 | 0.09 | 0.09 | 0.26 | 0.26 | 0.26 | 0.26 | 0.26 |
| (mol/kg) | | | | | | | | | | |
| Component B | | 0.13 | 0.13 | 0.13 | 0.13 | 0.06 | 0.13 | 0.13 | 0.06 | 0.06 |
| Component C | | 0.94 | 0.94 | 0.94 | 1.29 | 1.84 | 1.76 | 1.84 | 1.98 | 1.40 |
| Component D | Ammonium acetate | — | — | — | — | 1.17 | 1.17 | 1.17 | 1.17 | 0.78 |
| | Acetic acid | 0.78 | — | — | — | — | — | — | — | — |
| | Sodium acetate | — | 0.78 | — | — | — | — | — | — | — |
| | Acetic anhydride (×2) | — | — | 0.78 | — | — | — | — | — | — |
| | Propionic acid | — | — | — | 1.21 | — | — | — | — | — |
| | Succinic acid | — | — | — | — | — | 0.08 | — | — | — |
| | Lactic acid | — | — | — | — | — | — | 0.11 | — | — |
| | Malonic acid | — | — | — | — | — | — | — | 0.10 | — |
| | 2-Hydroxyisobutyric acid | — | — | — | — | — | — | — | — | 0.01 |
| Other | Hexaammonium | 0.003 | 0.003 | 0.003 | 0.003 | 0.002 | 0.003 | 0.003 | 0.002 | 0.002 |
| components | molybdate (×7) | | | | | | | | | |
| | Sulfuric acid | 0.04 | 0.4 | 0.06 | 0.1 | — | — | — | — | — |

| | | | | | | | | | |
|---|---|---|---|---|---|---|---|---|---|
| Component A/Component B molar ratio | 0.7 | 0.7 | 0.7 | 0.7 | 4.2 | 2.1 | 2.1 | 4.2 | 4.2 |
| Component C/component B molar ratio | 7.5 | 7.5 | 7.5 | 10.3 | 29.4 | 14.1 | 14.7 | 31.5 | 22.3 |
| Component D/Component B molar ratio | 6.2 | 6.2 | 6.2 | 9.7 | 18.6 | 10.0 | 10.2 | 20.2 | 12.6 |
| Layer structure of etching object | Three- | Three- | Three- | Three- | Three- | Three- | Three- | Three- | Two- |
| | layer | layer | layer | layer | layer | layer | layer | layer | layer |
| | structure | structure | structure | structure | structure | structure | structure | structure | structure |
| pH of liquid composition | 5 | 5 | 5 | 5 | 7 | 6 | 6 | 7 | 6.5 |
| Just etching time (sec) | 71 | 80 | 79 | 51 | 26-30 | 42-45 | 31-34 | 13-17 | 40-43 |
| Taper angle (degree) | 50 | 60 | 55 | 70 | 45 | 45 | 50 | 70 | 60 |
| Bottom CD loss (μm) | 1.1 | 1.3 | 1.2 | 1.4 | 0.8 | 0.7 | 0.6 | 0.9 | 0.5 |

### Example 26

A liquid composition was prepared in the same manner as in Example 24, except that a double salt of potassium hydrogen peroxomonosulfate, potassium hydrogen sulfate, and potassium sulfate (tradename Oxone (registered trademark), manufactured by DuPont) was used instead of ammonium peroxodisulfate as the component (A), and the liquid composition had a formulation shown in Table 5 below. The liquid composition thus obtained was sprayed (under 50% overetching conditions) on the molybdenum/copper/molybdenum/glass substrate with the resist pattern obtained in Reference Example 1 formed thereon. As a result, neither etching residue nor precipitates were observed, and both the taper angle and the bottom CD loss were also good. The evaluation results were as shown in Table 5. In Table 5, the content of the molybdate ion source was calculated as an amount of 7 times the content of hexaammonium molybdate in terms of orthomolybdate ions per kg of the liquid composition.

### Examples 27 and 28

Liquid compositions were prepared in the same manner as in Example 24, except that t-butylamine or tetramethylammonium hydroxide was added as a member belonging to the component (C) and the liquid composition had a formulation shown in Table 5 below. Spraying (under 50% overetching conditions) was carried out in the same manner as in Example 26, except that the liquid compositions obtained just above were used. As a result, neither etching residue nor precipitates were observed, and both the taper angle and the bottom CD loss were also good. The evaluation results were as shown in Table 5 below.

### Example 29

A liquid composition was prepared in the same manner as in Example 24, except that isopropylamine was added as a member belonging to the component (C), sodium peroxodisulfate was used instead of ammonium peroxodisulfate as the component (A), and the liquid composition had a formulation shown in Table 5 below. Spraying (under 50% overetching conditions) was carried out in the same manner as in Example 26, except that the liquid composition obtained just above was used. Neither etching residue nor precipitates were observed, and both the taper angle and the bottom CD loss were also good. The evaluation results were as shown in Table 5 below.

TABLE 5

| | | Example | Example | Example | Example |
|---|---|---|---|---|---|
| Components of liquid composition (mol/kg) | | 26 | 27 | 28 | 29 |
| Component A | Ammonium peroxodisulfate | — | 0.26 | 0.26 | — |
| | Sodium peroxodisulfate | — | — | — | 0.26 |
| | Double salt of potassium hydrogen | 0.44 | — | — | — |
| | peroxomonosulfate, potassium | | | | |
| | hydrogen sulfate, and potassium | | | | |
| | sulfate | | | | |
| Component B | | 0.06 | 0.06 | 0.06 | 0.06 |
| Component C | Ammonium peroxodisulfate(×2) | — | 0.53 | 0.53 | — |
| | Ammonia | 0.64 | — | — | — |
| | t-Butylamine | — | 0.36 | — | — |
| | Tetramethylammonium hydroxide | — | — | 0.32 | — |
| | Isopropylamine | — | — | — | 0.05 |
| | Ammonium acetate | — | — | — | 0.39 |
| | Hexaammonium molybdate (×6) | 0.001 | 0.001 | 0.001 | 0.001 |
| | Subtotal | 0.64 | 0.89 | 0.85 | 0.44 |
| Component D | Ammonium acetate | — | — | — | 0.39 |
| | Malonic acid | 0.14 | 0.14 | 0.14 | 0.19 |
| Other | Hexaammonium molybdate (×7) | 0.002 | 0.002 | 0.002 | 0.002 |
| component | | | | | |

| | | | | |
|---|---|---|---|---|
| Component A/Component B molar ratio | 7.0 | 4.2 | 4.2 | 4.2 |
| Component C/component B molar ratio | 10.2 | 14.2 | 13.6 | 7.0 |
| Component D/Component B molar ratio | 2.3 | 2.3 | 2.3 | 9.3 |
| Layer structure of etching object | Three-layer | Three-layer | Three-layer | Three-layer |
| | structure | structure | structure | structure |
| pH of liquid composition | 5.5 | 7.0 | 7.0 | 7.3 |
| Just etching time (sec) | 24-30 | 35-40 | 31-37 | 52-57 |
| Taper angle (degree) | 60 | 45 | 60 | 40 |
| Bottom CD loss (μm) | 1.4 | 0.7 | 0.8 | 1.2 |

### Example 30

A liquid composition was prepared in the same manner as in Example 24, except that maleic anhydride was added as a member belonging to the component (D), and phosphoric acid was added as one of other components in an amount of 0.005 mole per kg of the liquid composition and the liquid composition had a formulation shown in Table 6 below. Spraying (under 50% overetching conditions) was carried out in the same manner as in Example 26, except that the liquid composition obtained just above was used. Neither etching residue nor precipitates were observed, and both the taper angle and the bottom CD loss were also good. The evaluation results were as shown in Table 6 below.

### Examples 31 and 32

Liquid compositions were prepared in the same manner as in Example 24, except that phosphoric acid was added as one of other components and the liquid compositions had formulations shown in Table 6 below. Spraying (under 50% overetching conditions) was carried out in the same manner as in Example 26, except that the liquid compositions obtained just above were used. As a result, neither etching residue nor precipitates were observed, and both the taper angle and the bottom CD loss were also good. The evaluation results were as shown in Table 6 below. Example 33

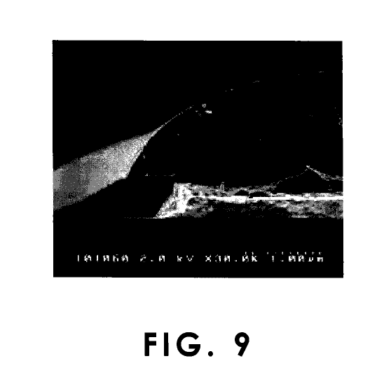

Spraying was carried out on the copper/molybdenum/glass substrate with the resist pattern obtained in Reference Example 2 in the same manner as in Example 25, except that the liquid composition prepared in Example 31 was used. The time taken until the transparent substrate was exposed (just etching time) was 42 sec, and the time taken until the transparent substrate was exposed at all the areas in the substrate was 43 sec. After etching for 63 sec (under 50% overetching conditons), the copper/molybdenum/glass substrate was rinsed with water (at room temperature for one min), was then dried with a blower, and was observed under an optical microscope. As a result, it was confirmed that the copper/molybdenum laminated film at its exposed areas, that is, areas other than areas covered with the patterned resist, was completely removed, and neither etching residue nor precipitates were observed on the glass substrate. After the etching treatment, the copper/molybdenum/glass substrate was broken, and the cross section of the substrate was observed under a scanning secondary electron microscope. As a result, it was found that the shape was a forward tapered one with a taper angle of 60 degrees, and the bottom CD loss was 0.4 μm. The evaluation results were as shown in Table 6 below. A secondary electron microscopic image of Example 33 is shown in FIG. 9.

### Comparative Example 6

A liquid composition was prepared in the same manner as in Example 24, except that the copper ion source (B) was not added, phosphoric acid was added as one of other components, and the liquid composition had a formulation shown in Table 6 below. Spraying (under 50% overetching conditions) was carried out in the same manner as in Example 26, except that the liquid composition obtained just above was used. In the liquid composition of Comparative Example 6 free from the copper ion source (B), even after etching for 400 sec, the molybdenum/copper/molybdenum laminated film at its exposed areas, that is, areas other than areas covered with the patterned resist, did not completely disappear, indicating that etching could not be successfully carried out. The evaluation results were as shown in Table 6.

TABLE 6

| Components of liquid composition | | Example | Example | Example | Example | Comparative |
|---|---|---|---|---|---|---|
| (mol/kg) | | 30 | 31 | 32 | 33 | Example 6 |
| Component A | | 0.26 | 0.88 | 0.88 | 0.88 | 0.26 |
| (ammonium peroxodisulfate) | | | | | | |
| Component B | | 0.06 | 0.06 | 0.06 | 0.06 | — |
| Component C | | 1.75 | 2.97 | 2.53 | 2.97 | 1.32 |
| Component D | Ammonium acetate | 0.78 | 0.78 | 0.78 | 0.78 | 0.39 |
| | Malonic acid | 0.14 | 0.14 | 0.14 | 0.14 | 0.19 |
| | Maleic anhydride | 0.10 | — | — | — | — |
| Other | Hexaammonium | 0.002 | 0.002 | 0.002 | 0.002 | 0.002 |
| components | molybdate (×7) | | | | | |
| | Phosphoric acid | 0.005 | 0.05 | 0.1 | 0.05 | 0.005 |
| | Sulfuric acid | — | — | 0.1 | — | — |

| | | | | | |
|---|---|---|---|---|---|
| Component A/Component B molar | 4.2 | 14.0 | 14.0 | 14.0 | — |
| ratio | | | | | |
| Component C/Component B molar | 27.9 | 47.4 | 40.4 | 47.4 | — |
| ratio | | | | | |
| Component D/Component B molar | 16.4 | 14.7 | 14.7 | 14.7 | — |
| ratio | | | | | |
| Layer structure of etching object | Three-layer | Three-layer | Three-layer | Two-layer | Three-layer |
| | structure | structure | structure | structure | structure |
| pH of liquid composition | 7.0 | 6.5 | 4.0 | 6.5 | 7.0 |
| Just etching time (sec) | 88-92 | 76-81 | 102-110 | 42-43 | 400 or longer |
| Taper angle (degree) | 45 | 25 | 70 | 60 | — |
| Bottom CD loss (μm) | 1.4 | 0.9 | 2.0 | 0.4 | — |

As is also apparent from the evaluation results, for all the liquid compositions of the Examples, neither residue nor precipitates were observed after etching. Emission of an odor of ammonia was not noticed during etching, and handling was easy. Further, the evolution of gas involved in a decomposition reaction of peroxosulfate ions was not also observed, and safe and stable etching could be carried out.

The etching liquid composition according to the present invention is suitable for a multilayer film containing copper and molybdenum and can etch a wiring having a multilayer structure containing copper and molybdenum at one time. Further, even when a flow rate distribution of the liquid composition was varied in a large-area etching apparatus, the etching rate is constant regardless of sites in the substrate and even etching can be realized, contributing to realization of high productivity and large-size displays.

1. (canceled)

2. The method of claim 11, wherein the peroxosulfate ion source (A) is at least one compound selected from the group consisting of ammonium peroxodisulfate, potassium peroxodisulfate, sodium peroxodisulfate, and potassium hydrogen peroxomonosulfate.

3. The method of claim 11, wherein the mixing ratio of the peroxosulfate ion source (A) to the copper ion source (B) is 0.01 to 20 on a molar basis.

4. The method of claim 11, wherein the copper ion source (B) is at least one compound selected from the group consisting of copper, copper sulfate, copper nitrate, and copper acetate.

5. The method of claim 11, wherein the nitrogen compound source (C) is at least one compound selected from the group consisting of ammonia, ammonium sulfate, ammonium nitrate, ammonium acetate, ammonium peroxodisulfate, and tetramethylammonium hydroxide.

6. The method of claim 11, wherein the mixing ratio of the nitrogen compound source (C) to the copper ion source (B) is 4 to 100 on a molar basis.

7. The method of claim 11, wherein the liquid composition further comprises (D) a carboxylate ion source.

8. The method of claim 7, wherein the carboxylate ion source (D) is at least one compound selected from the group consisting of acetic acid, propionic acid, malonic acid, succinic acid, lactic acid and salts of the carboxylic acids, and acetic anhydride.

9. The method of claim 7, wherein the mixing ratio of the carboxylate ion source (D) to the copper ion source (B) is 0.1 to 50 on a molar basis.

10. The method of claim 11, wherein the liquid composition further comprises (E) a molybdate ion source.

11. An etching method, comprising:
contacting a liquid composition with a multilayer film,
wherein the liquid composition comprises (A) a peroxosulfate ion source; (B) a copper ion source; and (C) at least one nitrogen compound source selected from the group consisting of ammonia, ammonium ions, amines, and alkyl ammonium ions,
wherein the liquid composition has a pH of from 3.5 to 9, and
wherein the multilayer film comprises copper and molybdenum.

12. The etching method according to claim 11, wherein the multilayer film has a two-layer structure composed of a layer of molybdenum or a compound composed mainly of molybdenum and a layer of copper or a compound composed mainly of copper that are stacked on each other.

13. The etching method according to claim 11, wherein the multilayer film has a three-layer structure consisting of a layer of molybdenum or a compound composed mainly of molybdenum, a layer of copper or a compound composed mainly of copper, and a layer of molybdenum or a compound composed mainly of molybdenum that are stacked in that order.

14. A process for producing a multilayer film wiring comprising a multilayer film provided on a substrate, the multilayer film comprising at least a molybdenum-containing layer and a copper-containing layer, the process comprising:
providing a layer of molybdenum and a layer of copper in that order on a substrate to form a multilayer film;
covering a resist on the multilayer film to form a resist film;
subjecting the resist film to exposure and development to form a predetermined resist pattern, thereby forming an etching object; and
contacting a liquid composition with the etching object to etch the multilayer film,
wherein the liquid composition comprises (A) a peroxosulfate ion source; (B) a copper ion source; and (C) at least one nitrogen compound source selected from the group consisting of ammonia, ammonium ions, amines, and alkyl ammonium ions, and
wherein the liquid composition has a pH of from 3.5 to 9.

15. The method of claim 11, wherein liquid composition is capable of etching a multilayer comprising a 200 angstrom layer of molybdenum, then a 5000 angstrom layer of copper, then a 200 angstrom layer of molybdenum at one time at an etching speed of from 0.1 to 1 micron/min.

16. The method of claim 11, wherein the multilayer film is on a substrate, and wherein contacting the liquid composition with the multilayer film comprises etching the multilayer film, thereby obtaining a forward tapered angle of from 15 to 75 degrees to the substrate, and a CD loss of not more than 2.5 microns.
